(19) United States
(12) Patent Application Publication
(10) Pub. No.: US 2009/0014130 A1
(43) Pub. Date: Jan. 15, 2009

(54) Photovoltaic awning system

(76) Inventor: David C. Heidenreich, Akron, OH (US)

Correspondence Address: RENNER KENNER GREIVE BOBAK TAYLOR & WEBER, FIRST NATIONAL TOWER FOURTH FLOOR, 106 S. MAIN STREET, AKRON, OH, 44308, US

(21) Appl. No.: 11/827,182

(22) Filed: Jul. 11, 2007

(51) Int. Cl. E04F 10/06; H01L 31/042

(52) U.S. Cl. 160/66; 136/246

(57) ABSTRACT

A deployable and retractable photovoltaic awning assembly is formed from a flexible sheet of photovoltaic devices attached to a rotatable roll at one end and a boom at the other. A pair of side support tubes are provided with tracks that receive slides maintained on opposite ends of the boom. At least one of the slides is axially movable with respect to the boom, ensuring engagement of the slides in the tracks as the boom is moved away from and toward the roll during deployment and retraction of the flexible sheet. In this regard, the slides are mounted on pins through articulated joints of the spherical/universal type. The sheet of flexible voltaic devices is preferably transmissive as to light wave lengths in the range required for vegetation photosynthesis, and absorbert for all other ranges, allowing the awning to be deployed over vegetated areas, without interference with the photosynthesis process. Moreover, the awning may be retractable in periods of rain or the like, ensuring that the vegetation is properly and naturally attended.

### TECHNICAL FIELD

The invention herein resides in the art of electrical energy producing systems and, more particularly, to such systems that employ photovoltaic devices that serve to convert light energy into electrical energy. More particularly, the invention relates to a photovoltaic energy producing system implemented in the form of a deployable and retractable awning having a substantially rigid frame. Further, the invention relates to a photovoltaic awning system particularly adapted from thin film photovoltaic materials that is configured to maintain its integrity in high winds, provide a structure for effectively transmitting the energy produced to a distribution system, and that is readily deployed and retracted. The thin film photovoltaic materials and the carrier material upon which they are received are further characterized by their light transmissive features. Optimally, these materials pass light in the photosynthesis wavelength band(s) to vegetation below, while converting the remaining responsive wavelengths into electrical energy through the photovoltaic medium.

### BACKGROUND ART

The use of photovoltaic devices to convert light energy into electrical energy is commonly known. However, the physical structure of such systems require custom design and field installation of multiple modules to generate sufficient energy to meet the power needs of even small commercial or residential buildings.

The problems of the prior art are aggravated when photovoltaic devices are contemplated for deployment in a retractable awning-like structure. Indeed, winds and snow loads are significant barriers to the use of anything but formidable structures to carry power generating systems of photovoltaic devices. The physical size of an awning required to generate significant amounts of electrical energy frustrate efforts of deployment and retraction, which are required to avoid damage or destruction when inclement weather or high winds rapidly approach. A photovoltaic awning structure that overcomes many of the deficiencies of the prior art is presented in copending patent application Ser. No. 11/442,564, filed May 20, 2006, entitled Photovoltaic Awning Structures, by the inventor herein. The teachings of that application are incorporated herein by reference.

When used in an awning structure, the photovoltaic system substantially blocks the passage of light to regions below the awning. While this may be acceptable where shade is desired, such as coverings on carports, patios and the like, it is problematic when the awning is to cover areas where vegetation is grown, or sunlight is otherwise desired.

There remains a need in the art for a photovoltaic awning structure that may be quickly and easily deployed and retracted, that demonstrates a high degree of stability in windy environments, that facilitates and accommodates ease of generation and transmission of electrical power therefrom and that can be light transmissive, within desired wavelengths.

### DISCLOSURE OF INVENTION

In light of the foregoing, it is a first aspect of the invention to provide a photovoltaic deployable and retractable awning structure that demonstrates a high degree of stability in windy environments.

A further aspect of the invention is the provision of a photovoltaic deployable and retractable awning structure that is quickly and easily deployed and retracted.

Another aspect of the invention is the provision of a photovoltaic deployable and retractable awning structure that employs thin film photovoltaic materials.

Still another aspect of the invention is the provision of a photovoltaic deployable and retractable awning structure in which the awning is light transmissive in a range of wavelengths for vegetative photosynthesis.

Yet a further aspect of the invention is the provision of a photovoltaic deployable and retractable awning structure, capable of blocking and transmitting particular light wavelengths, and that is cost effective and easy to implement, providing for stability and physical integrity in use, and capable of generating a significant amplitude of electrical power, while being easy to deploy and retract, and that can be constructed with presently known state of the art elements.

The foregoing and other aspects of the invention that will become apparent as the detailed description proceeds are achieved by a deployable and retractable photovoltaic awning assembly, comprising: a sheet of photovoltaic devices; a rotatable roll receiving said sheet and adapted to alternatively rotatably pay-out said sheet and retract and retrieve said sheet; a boom at an end of said sheet opposite said roll; a cable connected to said boom at each of opposite ends thereof, said cables being windingly received by said roll; a pair of side support tubes extending along opposite edges of said sheet between said ends of said boom and said roll; and wherein said sheet has positioned therealong a plurality of elongated strips of photovoltaic materials.

Further aspects of the invention that become apparent herein are achieved by a deployable and retractable photovoltaic awning assembly, comprising: a sheet of photovoltaic devices; a rotatable roll receiving said sheet and adapted to alternatively rotatably pay-out said sheet and retract and retrieve said sheet; a boom at an end of said sheet opposite said roll; a cable connected to said boom at each of opposite ends thereof, said cables being windingly received by said roll; a pair of side support tubes extending along opposite edges of said sheet between said ends of said boom and said roll; and wherein said sheet has positioned therealong a plurality of elongated strips of photovoltaic materials; and wherein said sheet substantially absorbs the solar spectrum outside the range of 400-700 nanometers wavelength for generation of electric power, and passes the range of 400-700 nanometers wavelength for photosynthesis by plants therebeneath.

### BRIEF DESCRIPTION OF DRAWINGS

For a complete understanding of the various aspects of the invention, reference should be made to the following detailed description and accompanying drawings wherein:

FIG. 1 is a perspective view of a photovoltaic awning structure particularly adapted for residential use and made in accordance with the invention;

FIG. 2 is a perspective view of the frame and slide structure of the device of FIG. 1;

FIG. 3 is a cross sectional view of the boom track and slide assembly made in accordance with the invention, showing the same in arrangement to accommodate variations in track spacing encountered deployment, and retraction; and

FIG. 4 is a graph illustrating the light spectrum in association with the needs of vegetation for photosynthesis.

### BEST MODE FOR CARRYING OUT THE INVENTION

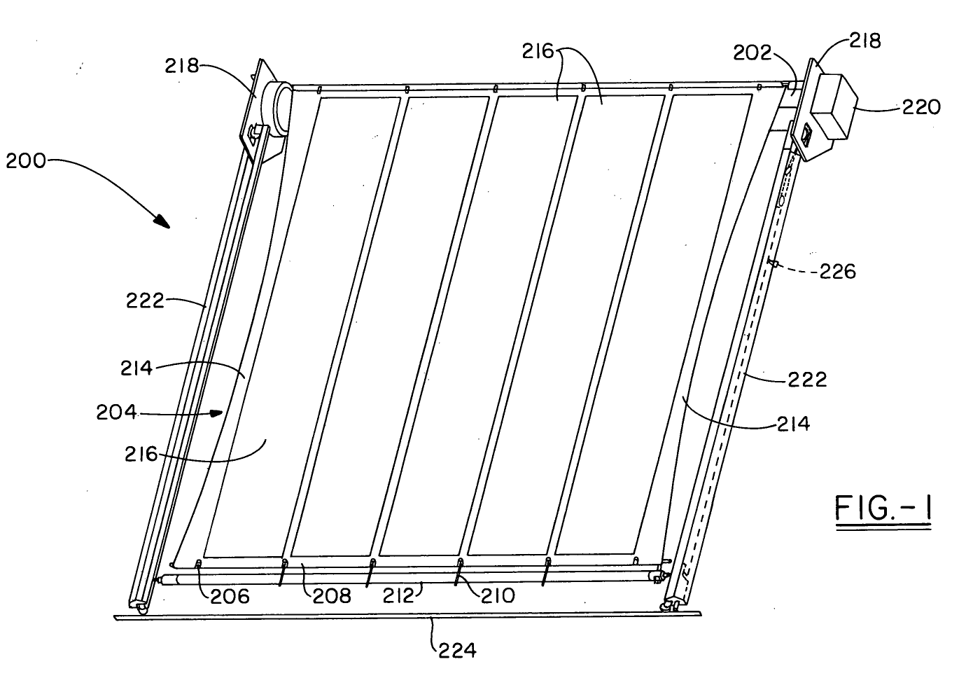

Referring now to the drawings and more particularly FIG. 1, it can be seen that an embodiment of a photovoltaic awning made in accordance with the invention is designated generally by the numeral 200. The awning assembly 200 includes a cylindrical roll 202, securedly receiving one end of an awning 204. The other end of the awning 204 receives a rod 206 through a sleeve 208 formed therein. A plurality of ties 210 secure the rod 208 to a boom 212.

According to the invention, the awning 204 includes a carrier base material 214, which receives one or more photovoltaic materials or devices 216 thereon. The webs of photovoltaic material 216 may be sewn, bonded, or otherwise affixed to the carrier base material 214, as will be readily appreciated by those skilled in the art. Additionally, it is contemplated that the webs of photovoltaic materials or devices 216 may be overlaid upon the carrier base material 214 or, alternatively, the carrier base material 214 may be characterized by openings or voids that are covered by the photovoltaic material webs 216. It is particularly contemplated that the photovoltaic material 216 will be of the flexible thin film type, given to the capability of being repeatedly rolled and unrolled during deployment and retrieval, without damage.

As further shown in FIG. 1, a pair of mounting brackets 218 is provided, with one mounting bracket on each of opposite ends of the cylindrical roll 202. A control box 220, having a motor therein drivably connected to the cylindrical roll 202 is provided in association with at least one of the mounting brackets 218. Those skilled in the art will appreciate that the mounting brackets 218 are adapted to secure the photovoltaic awning assembly 200 to appropriate posts, frame members, building structures, or the like.

Uniquely provided in association with the photovoltaic awning assembly 200 are a pair of side support tubes 222, fixed at one end to an associated bracket 218, and at the other end to a cross tube 224. Accordingly, the cylindrical roll 202, side support tubes 222 and cross tube 224 effectively define a frame member for receiving and supporting the awning 204, as shown in FIG. 1. A spring/pulley assembly 226 is provided in association with each of the side support tubes 222 and the boom 212 to assist in deploying and retracting the awning 204 under control of the motor of the control box 220. This structure and operation can proceed as previously stated herein, or as may be appreciated by those skilled in the art.

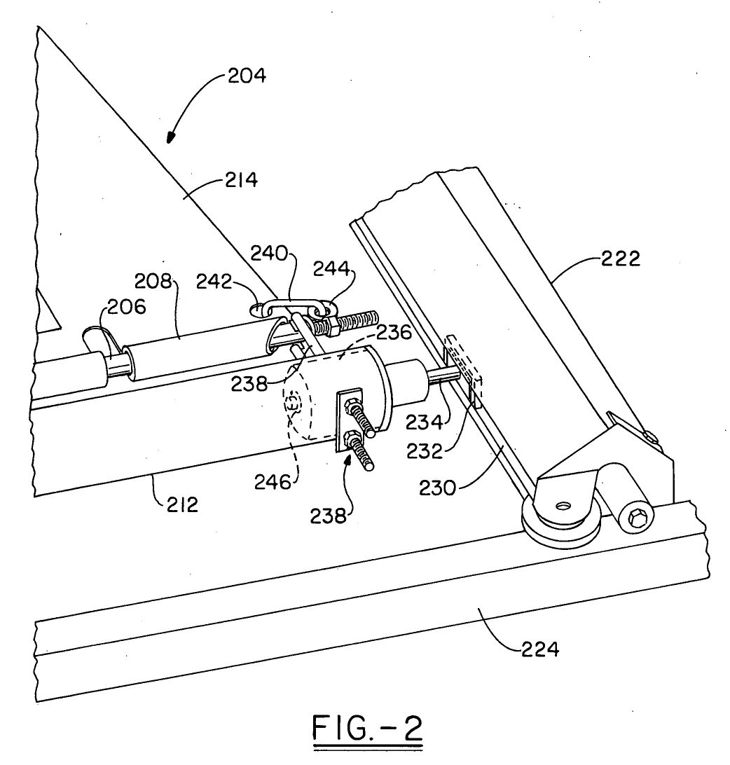

With continued reference to FIG. 1 in conjunction with FIG. 2, it can be seen that each of the side support tubes 222 is characterized by a track 230 extending along an interior side thereof. The tracks 230 are characterized by a pair of overturned lips, adapted to slidingly receive and capture a slide 232 therein. Each slide 232 is connected to a pin or axle 234 received within a tubular housing 236 which, in turn, is securedly received within and caps opposite ends of the boom 212. Each tubular housing 236 is secured to the rod 206 by means of a U-bolt 238, or the like. Also provided at each end of the rod 206 is a ring coupler 240, adapted to secure the carrier base material 214 to the rod 206 by secure engagement between the aperture 242 in the base material 214 and ring 244 connected to the rod 206.

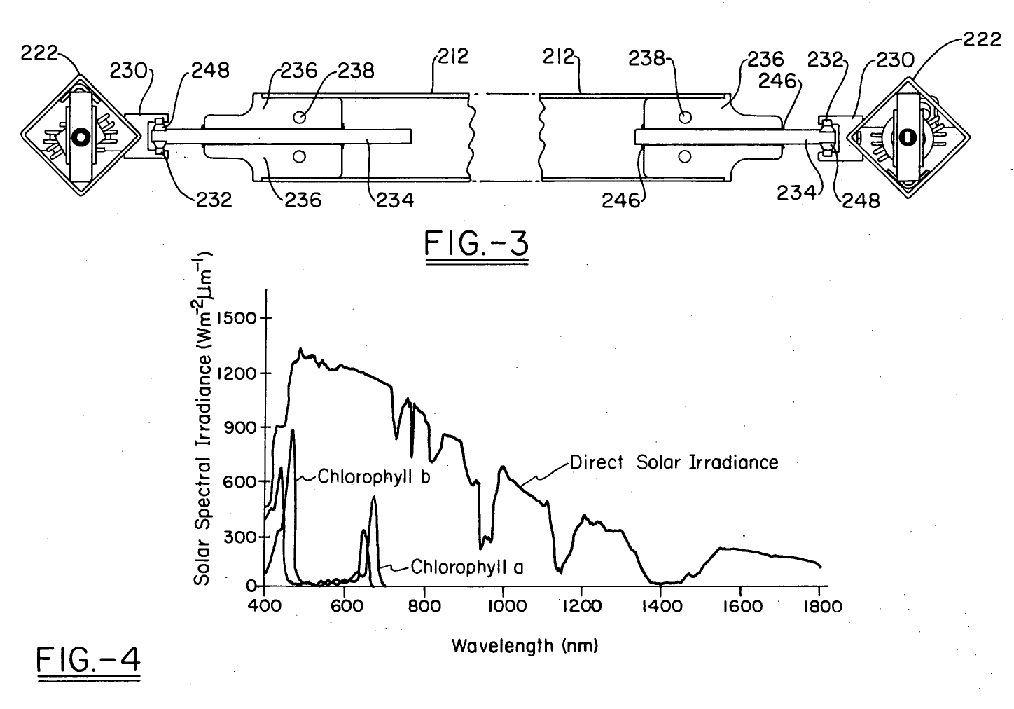

With reference now to FIGS. 2 and 3, it will be appreciated that the pin 234 in the rightmost assembly shown in FIG. 3 is secured to the tubular housing 236 by keeper rings 246, secured on either side of the housing 236. Accordingly, in one embodiment of the invention, the pin 234 in this assembly does not move laterally within the housing 236. To the contrary, in the assembly to the left of the illustration of FIG. 3, the pin 234 is slidably received within the tubular housing 236 to account for differences in spacings between the side support tubes 222 and associated tracks 230. As will become apparent below, the side support tubes 222 are typically other than coplanar and parallel to each other, in order to impart a saddle configuration into the awning 204 to ensure and maintain the structural integrity of the awning to withstand wind loads and the like. To further assist in the movement of the slides 232 within the tracks 230, the associated pins 234 are secured to the slides 232 by means of articulated spherical or universal joints 248. Accordingly, with at least one of the pins 234 being slidably received within the housing 236, and with each of the pins 234 being mounted by a spherical joint 248 to the associated slide 232, the boom 212 may be deployed and retracted by means of the motor of the control box 220 regardless of differences in elevation of the side support tubes 222 at the points at which the slides 232 are received by the tracks 230.

Those skilled in the art will appreciate that, in order to impart a saddle configuration into the awning 204, it is most desired that the side support tubes 222 not be coplanar and parallel, but that the end of one of the side support tubes 222 at its point of engagement with the cross tube 224 be higher or lower than the elevation of the end of the other side support tube 222 at its point of interconnection with the cross tube 224. With this skewed arrangement, movement of the slides 232 within the tracks 230 is facilitated by the sliding movement of at least one of the pins 234, and the large degree of universal movement accommodated by the spherical or universal joints 248.

Deployment and retraction of the awning assembly 200 is attained as previously presented herein. However, the awning assembly 200 is provided with a substantially rigid frame, to which the awning 204 is continually engaged, such that the likelihood of the awning 204 falling or otherwise presenting a precarious situation is greatly reduced.

Also contemplated as a portion of the present invention is the implementation of an awning structure fabricated from a photovoltaic material 216 and carrier base material 214 that is layered, encapsulated, or bonded to an underlying carrier base material that is transparent or translucent. Such materials may be developed to allow for the passage of specific wavelengths of the light spectrum, while filtering the rest. Accordingly, awnings of the type presented herein may be fashioned from a combination of materials that allow for the passage of specific light ranges that are beneficial to photosynthesis and plant growth. Accordingly, an awning may be employed to generate electricity from solar power, while still allowing the passage of light wavelengths that are beneficial to vegetation planted therebelow.

It has been found that wavelengths of electromagnetic energy from the sun that reaches the earth's surface range from about 300 to over 2000 nanometers. The visible light range is from 380 to 740 nanometers. Accordingly, about half of the solar energy incident to the earth is outside this visible range, mostly at longer wavelengths. The wavelengths needed for plants for photosynthesis form an even narrower wave band, on the order of 400-700 nanometers. Even within this range, much of that spectrum is not needed for plant growth, especially the green band from 490 to 620 nanometers. Moreover, particular plant types use even narrower ranges.

With reference to FIG. 4, it will be appreciated that photosynthesis occurs in two distinct regions in the solar spectrum. The first is in the wavelength range of 400-490 nanometers, and the second in the range of 620-700 nanometers. Accordingly, even within the range of 400-700 nanometers, the green band between 490-620 nanometers is not required for photosynthesis, and can be used for generation of electrical energy. The invention contemplates the construction of a photovoltaic awning in which the wavelengths necessary for photosynthesis are passed through the awning, while the other wavelengths are captured by the photovoltaic materials for the generation of electric energy.

This concept of the invention, passing light ranges necessary for photosynthesis while capturing the remaining wavelengths for the generation of energy is applicable to a broad range of photovoltaic awnings consistent with any of various other features presented and described herein.

A retractable photovoltaic awning as described that selectively allows the photosynthesis wavelengths to pass through can also selectively allow rain water to nourish the vegetation below it by retracting at night or on rainy days when the insolation is normally low.

Thus it can be seen that the various aspects of the invention have been attained by the structure presented and described above. While in accordance with the patent statutes, only the best mode and preferred embodiment of the invention have been presented and described in detail, the invention is not limited thereto or thereby. Accordingly, for an appreciation of the true scope and breadth of the invention, reference should be made to the following claims.

What is claimed is:

1. A deployable and retractable photovoltaic awning assembly, comprising:
a flexible sheet of photovoltaic devices;
a rotatable roll receiving said sheet and adapted to alternatively rotatably pay-out said sheet and retract and retrieve said sheet;
a boom at an end of said sheet opposite said roll;
a cable connected to said boom at each of opposite ends thereof, said cables being windingly received by said roll;
a pair of side support tubes extending along opposite edges of said sheet between said ends of said boom and said roll; and
wherein said sheet has positioned therealong a plurality of elongated strips of photovoltaic materials.

2. The deployable and retractable photovoltaic awning assembly as recited in claim 1, further comprising a track extending along each of said side support tubes.

3. The deployable and retractable photovoltaic awning assembly as recited in claim 2, wherein said boom has a slide at each of opposed ends thereof, each said slide being received in a uniquely associated one of said tracks.

4. The deployable and retractable photovoltaic awning assembly as recited in claim 3, wherein each said slide is slidingly captured and retained in said track.

5. The deployable and retractable photovoltaic awning assembly as recited in claim 4, wherein each said slide is connected to a respective pin extending from a respective end of said boom.

6. The deployable and retractable photovoltaic awning assembly as recited in claim 5, wherein said slides are connected to said pins by articulated joints.

7. The deployable and retractable photovoltaic awning assembly as recited in claim 6, wherein said articulated joints are spherical joints.

8. The deployable and retractable photovoltaic awning assembly as recited in claim 6, wherein said articulated joints are universal joints.

9. The deployable and retractable photovoltaic awning assembly as recited in claim 6, wherein at least one of said pins is axially slidably received by said boom.

10. The deployable and retractable photovoltaic awning assembly as recited in claim 9, wherein said tracks are neither parallel nor coplanar.

11. The deployable and retractable photovoltaic awning assembly as recited in claim 10, wherein said side support tubes are interconnected by a cross tube at ends thereof opposite said roll.

12. The deployable and retractable photovoltaic awning assembly as recited in claim 11 wherein said roll, side support tubes and cross tube define a frame receiving and containing said sheet.

13. The deployable and retractable photovoltaic awning assembly as recited in claim 1, wherein said sheet is partially transparent.

14. The deployable and retractable photovoltaic awning assembly as recited in claim 13, wherein said sheet substantially absorbs the solar spectrum outside the range of 400-700 nanometers wavelength for generation of electric power, and passes the range of 400-700 nanometers wavelength for photosynthesis by plants therebeneath.

15. The deployable and retractable photovoltaic awning assembly as recited in claim 14, wherein a substantial part of the solar spectrum within the wavelength range of 490-620 nanometers is absorbed for generation of electric power.
